(19) United States
(12) Patent Application Publication
(10) Pub. No.: US 2006/0096541 A1
(43) Pub. Date: May 11, 2006

(54) Apparatus and method of forming a layer on a semiconductor substrate

(76) Inventors: Jung-Hun Seo, Gyeonggi-do (KR); Young-Wook Park, Gyeonggi-do (KR); Jin-Gi Hong, Gyeonggi-do (KR); Kyung-Bum Koo, Gyeonggi-do (KR); Eun-Taeck Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/258,673

(22) Filed: Oct. 25, 2005

(30) Foreign Application Priority Data
Nov. 8, 2004 (KR) 2004-90301

(51) Int. Cl. C23C 16/00

(52) U.S. Cl. 118/724; 118/715; 427/248.1

(57) ABSTRACT

In an apparatus for forming a layer, the apparatus includes a processing chamber, a chuck, a gas-supplying unit, and a pipe unit. The chuck for supporting a substrate is disposed in the processing chamber. The gas-supplying unit supplies a source gas for forming a layer on the substrate and a purge gas for purging the inside of the processing chamber to the processing chamber. The pipe unit transfers the source gas and the purge gas to the processing chamber at a temperature that falls between the temperature of condensation and a reaction temperature for the source gas so that condensation or deposition reaction does not occur until the source gas enters the processing chamber. A heater located outside of the chamber heats the purge gas that is supplied to the processing chamber to a predetermined temperature.

### BACKGROUND OF THE INVENTION

1. Cross-References to Related Applications

This application claims priority under 35 USC § 119 to Korean Patent Application No. 2004-90301, filed on Nov. 8, 2004, the contents of which are herein incorporated by reference in its entirety.

2. Field of the Invention

The present invention relates to an apparatus and a method of forming a layer. More particularly, the present invention relates to an apparatus and a method of forming a layer such as a titanium nitride layer on a substrate, such as a semiconductor wafer.

3. Description of the Prior Art

Thin films or layers are formed, patterned, and planarized on a semiconductor substrate to form circuits of the resulting semiconductor device. Such layers may be formed by any one of many different known processes, such as chemical vapor deposition (CVD), physical vapor deposition (PVD), and atomic layer deposition (ALD), etc. A silicon oxide layer, such as used as a gate insulation layer or an insulation interlayer of a semiconductor device, may for example be formed by a CVD process. A silicon nitride layer, used as a mask pattern, a gate spacer, etc., may also be formed by the CVD process. Additionally, various metal layers may be formed on the semiconductor substrate for forming a metal wire, an electrode, etc., by the CVD process, the PVD process, the ALD process, etc.

An important deposition layer in semiconductor processing is the titanium nitride layer, which may be used as a metal barrier layer for preventing a metal from diffusing. That is, the titanium nitride layer prevents a metal from diffusing into a lower region of a semiconductor device such as a gate of a transistor, a dielectric layer of a capacitor, or a semiconductor substrate. As with the metal layers, the titanium nitride layer may be formed by the CVD process, the PVD process, the ALD process, etc. Examples of methods for forming a titanium nitride layer are disclosed in U.S. Pat. Nos. 6,436,820 and 6,555,183.

A conventional method for forming the titanium nitride layer includes mixing a first source gas, including a TiCl₄ gas, with a second source gas, including an NH₃ gas. The source gases are supplied from a gas-supplying unit to a processing chamber through a showerhead. Temperature control during the deposition process is very important because different temperatures result in different deposition effects. The TiCl₄ gas condenses at a temperature of no more than about 70° C. and thereby acts as a (sometimes unwanted) particle source. Furthermore, an NH₄C1 powder is generated by a reaction between the TiCl₄ gas and the NH₃ gas at temperatures no more than about 130° C. Finally, the TiCl₄ gas is reacted with the NH₃ gas to form a titanium layer or titanium nitride layer at a temperature of about 280° C. and about 350° C. Accordingly, the pipe for supplying the TiCl₄ gas may be heated using a heating jacket at a temperature of about 150° C.

Localized temperature control is detrimentally affected, however, when the first source gas and the second source gas are mixed with each other. A temperature of the TiCl₄ gas may be radically changed when mixed with the second source gas so that the pipe or the showerhead may be contaminated due to the temperature alteration. Also, during a purging process where the TiCl₄ gas remaining in the pipe or the showerhead and the purge gas are mixed, a temperature of the TiCl₄ gas may be changed so that the pipe or the showerhead may become contaminated.

Contamination generated in the pipe or the showerhead also generally causes accompanying contamination to the semiconductor substrate so that failures of the semiconductor device are generated and the resulting semiconductor device has a deteriorated capacity.

Accordingly, the need remains for a method and apparatus capable of reducing contamination caused by unwanted alterations of source gas temperatures during layer deposition on a substrate.

### SUMMARY OF THE INVENTION

In accordance with one aspect of the present invention, an apparatus for forming a layer includes a processing chamber, a chuck, a gas-supplying unit, pipe units, and a heater. The chuck for supporting a substrate is positioned in the processing chamber. The gas-supplying unit supplies a source gas for forming a layer on the substrate and a purge gas for purging the inside of the processing chamber to the processing chamber. The pipe unit transfers the source and purge gases to the processing chamber. The heater heats the purge gas that is supplied to the processing chamber at a predetermined temperature.

According to one embodiment, the gas-supplying unit includes a first gas-supplying unit for supplying a first source gas to the processing chamber, a second gas-supplying unit for supplying a second source gas to the processing chamber, and a third gas-supplying unit for supplying the purge gas to the processing chamber. Here, the first gas includes a TiCl₄ gas and a first carrier gas. The second gas includes an NH₃ gas and a second carrier gas.

According to another embodiment, the pipe unit includes a main pipe for transferring the source gas and the purge gas, a first pipe connected between the main pipe and the processing chamber to transfer the first source gas to the processing chamber, a second pipe connected between the main pipe and the processing chamber to transfer the second source gas to the processing chamber, and a third pipe connected between the main pipe and the processing chamber to transfer the purge gas to the processing chamber.

According to still another embodiment, the first and second source gases have a temperature of about 180° C. to about 250° C. The heater is provided to the third pipe to heat the purge gas at a temperature substantially identical to that of the first and second source gases. The heater includes a heating block having the spiral passage and a heating coil for heating the heating block.

According to the present invention, the TiCl₄ gas may not be condensed in the pipes for supplying the source gases, and the processing chamber due to the temperature alteration, so that contamination of the semiconductor substrate may be suppressed. Also, a titanium layer or a titanium nitride layer may not be formed in the pipes.

In a method for forming a layer in accordance with another aspect of the present invention, a source gas is applied to a substrate in a processing chamber through a pipe to form a layer on the substrate. A purge gas is introduced into the processing chamber through the pipe to purge an inner space of the processing chamber. Here, the purge gas has a temperature for preventing the source gas from being condensed.

### BRIEF DESCRIPTION OF THE DRAWINGS

The above and other features and advantages of the present invention will become more apparent by describing in detailed exemplary embodiments thereof with reference to the accompanying drawings, in which:

FIG. 1 is a schematic view illustrating an apparatus for forming a layer in accordance with one exemplary embodiment of the present invention;

FIG. 2 is a partially cross sectional view illustrating a first gas-supplying unit used in the device of FIG. 1;

FIG. 3 is a cross sectional view illustrating a spiral block heater constructed according to a preferred embodiment of the invention as used in the apparatus of FIG. 1;

FIG. 4 is a schematic view illustrating an apparatus for forming a layer in accordance with another exemplary embodiment of the present invention; and

FIG. 5 is a flow chart illustrating a method of forming a layer in accordance with one exemplary embodiment of the present invention.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### An Apparatus for Forming a Layer

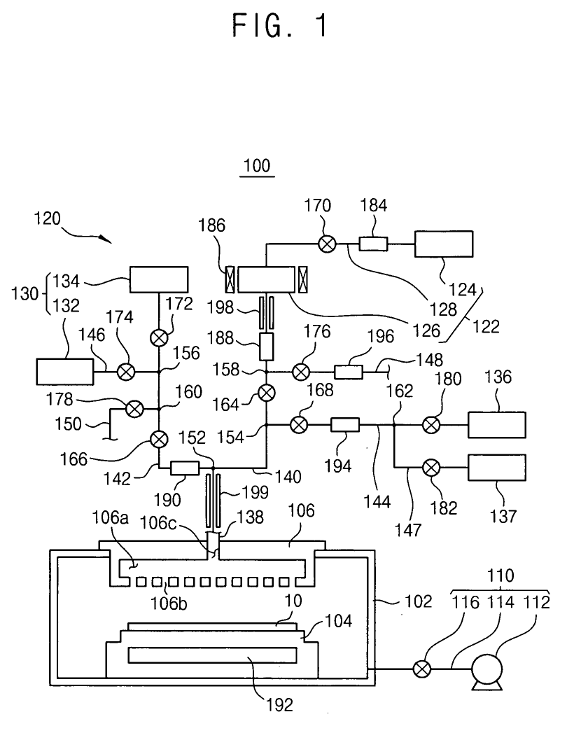

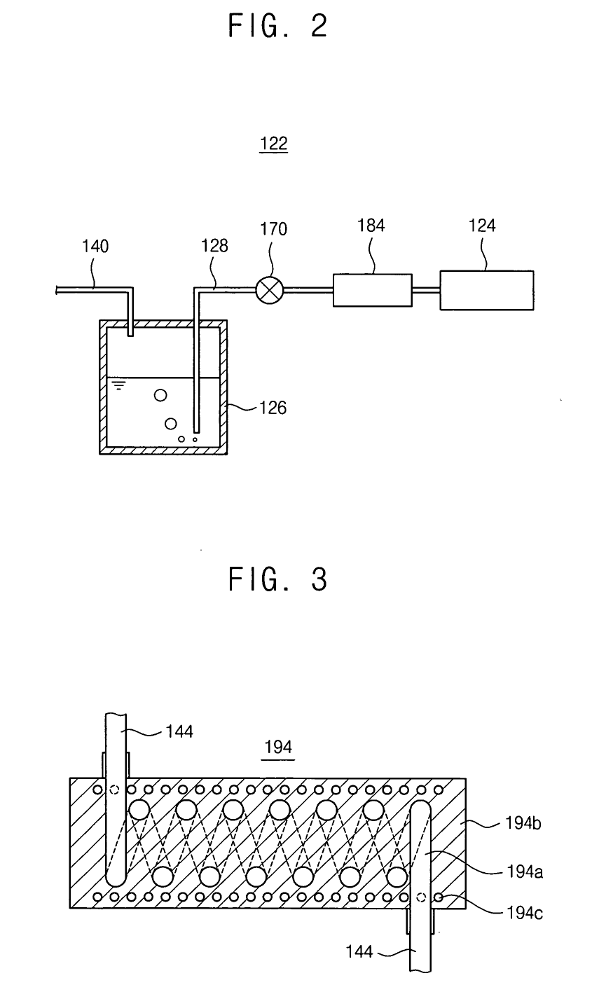

FIG. 1 is a schematic view illustrating an apparatus for forming a layer in accordance with one exemplary embodiment of the present invention, and FIG. 2 is a partially cross sectional view illustrating a first gas-supplying unit in FIG. 1.

Referring to FIG. 1, an apparatus 100 for forming a layer in accordance with the present embodiment may be used for forming a layer on a semiconductor substrate 10, for example, a semiconductor wafer. In particular, the apparatus 100 may be used for forming a titanium nitride layer on the semiconductor substrate 10. The apparatus 100 includes a process chamber 102, a chuck 104, and a gas-supplying unit 120.

The process chamber 102 provides a closed space in which a process is performed for forming the layer on the semiconductor substrate 10. The chuck 104 for supporting the semiconductor substrate 10 is disposed in the process chamber 102. The process chamber 102 is connected to a vacuum system 110 for exhausting byproducts, remaining gases, and a purge gas.

The gas-supplying unit 120 supplies source gases for forming the layer on the semiconductor substrate 10 on the chuck 104, and the purge gas for purging the process chamber after forming the layer. A showerhead 106 is disposed at an upper portion of the process chamber 102 so as to uniformly supply the source and purge gases to the process chamber 102. The showerhead 106 is connected to the gas-supplying unit 120.

Particularly, the gas-supplying unit 120 includes a first gas-supplying unit 122 for supplying a first source gas that includes a titanium tetrachloride (TiCl₄) gas and a first carrier gas to the process chamber 102, a second gas-supplying-unit 130 for supplying a second source gas that includes an ammonia (NH₃) gas and a second carrier gas to the process chamber 102, and a third gas-supplying unit 136 for supplying the purge gas to the process chamber 102. The gas-supplying unit 120 is connected to the showerhead 106 through a pipe unit.

Referring to FIG. 2, the first gas-supplying unit 122 includes a first container 124 for containing the first carrier gas, a closed vessel 126 for receiving a liquid TiCl₄ solution, and a dipped pipe 128 extending from the first container 124 into the closed vessel 126. In particular, the dipped pipe 128 has a first end connected to the first container 124, and a second end dipped into the liquid TiCl₄ solution in the closed vessel 126. The first source gas is formed by bubbling the first carrier gas supplied through the dipped pipe 128.

However, the first gas-supplying unit 122 may include a vaporizer. The vaporizer directly heats the liquid TiCl₄ solution to form a TiCl₄ gas. Alternatively, the vaporizer may form the liquid state of TiCl₄ into a misty state of TiCl₄. The vaporizer then heats the misty state of TiCl₄ to form a TiCl₄ gas.

The second gas-supplying unit 130 includes a second container 132 for containing a second carrier gas, and an NH₃ tank 134 for providing an NH₃ gas to the process chamber 102. The third gas-supplying unit 136 includes a third container for providing the purge gas to the process chamber 102.

The showerhead 106 includes a lower plate and an upper plate. The showerhead 106 has a space 106a for receiving the gases. The lower plate has a plurality of gas-spraying holes 106 for uniformly supplying the gases to the process chamber 102. The upper plate has a gas-supplying hole 106c for introducing the gases into the space 106a. The gases are supplied to the space 106a through a main pipe 138 that is connected to the gas-supplying hole 106c. The main pipe 138 is connected to the gas-supplying unit 120 through a plurality of sub-pipes.

The main pipe 138 and the closed container 126 of the first gas-supplying unit 122 are connected through a first pipe 140. The main pipe 138 and the NH₃ tank 134 of the second gas-supplying unit 130 are connected through a second pipe 142. The third gas-supplying unit 136 is connected to the first pipe 140 through a third pipe 144. The second container 132 of the second gas-supplying unit 130 is connected to the second pipe 142 through a fourth pipe 146. As depicted in FIGS. 1 and 2, the purge gas is supplied to the showerhead 106 through the third pipe 144, the first pipe 140 and the main pipe 138. Alternatively, the third pipe 144 may be directly connected to the second pipe 142.

Meanwhile, a first connecting member 152 is connected among the main pipe 138, the first pipe 140, and the second pipe 142. A second connecting member 154 is connected between the first pipe 140 and the third pipe 144. A third connecting member 156 is connected between the second pipe 142 and the fourth pipe 146.

A first valve 164 for adjusting a flux of the first source gas is installed in the first pipe 140 between the first gas-supplying unit 122 and the second connecting member 154. A second valve 166 for adjusting a flux of the second source gas is installed in the second pipe 142 between the first connecting member 152 and the third connecting member 156. A third valve 168 for adjusting a flux of the purge gas is installed in the third pipe 144 between the second connecting member 154 and the third gas-supplying unit 136. A fourth valve 170 for adjusting a flux of the first carrier gas is installed in the dipped pipe 128. The fifth valve 172 for adjusting a flux of the NH₃ gas is installed in the second pipe 142 between the third connecting member 156 and the NH₃ tank 134 of the second gas-supplying unit 130. A sixth valve 174 for adjusting a flux of the second carrier gas is installed in the fourth pipe 146.

A first bypassing pipe 148 for bypassing the first source gas is connected to the first pipe 140 between the first valve 164 and the closed container 126 of the first gas-supplying unit 122 through a fourth connecting member 158. A second bypassing pipe 150 for bypassing the second source gas is connected to the second pipe 142 between the second valve 166 and the third connecting member 156 through a fifth connecting member 160. A seventh valve 176 and an eighth valve 178 are installed in the first and second bypassing pipes 148 and 150, respectively.

A fourth gas-supplying unit 137 for supplying a cleaning gas to the processing chamber 102 is connected to the third pipe 144 through the fifth pipe 147. The fifth pipe 147 is connected to the third pipe 144 between the third valve 168 and the third gas-supplying unit 136 through a sixth connecting member 162. A ninth valve 180 is installed in the third pipe 144 between the sixth connecting member 162 and the third gas-supplying unit 136. A tenth valve 182 is installed in the fifth pipe 147.

The first carrier gas, the second carrier gas, and the purge gas may include an argon (Ar) gas. Alternatively, the first carrier gas, the second carrier gas and the purge gas may include an N₂ gas. In the present embodiment, the gas-supplying unit 120 includes the first container 124 for containing the first carrier gas, the second container 132 for containing the second carrier gas, and the third container 136 for containing the purge gas. Alternatively, the gas-supplying unit 120 may provide the first carrier gas, the second carrier gas, and the purge gas using a unique container.

A first heater 184 for heating the first carrier gas that is transferred from the first container 124 is installed in the dipped pipe 128 between the fourth valve 170 and the first container 124. The first heater 184 heats the first carrier gas to a first temperature. Heat generated from the first heater 184 improves vapor efficiency of the TiCl₄ gas. The first temperature may be above a condensing temperature of the TiCl₄ gas. For example, the first temperature is in a range of about 100 to about 180° C., preferably about 150° C.

A second heater 186 is connected to the closed container 126 so as to heat the closed container 126. The second heater 186 enhances a vapor efficiency of the TiCl₄ solution. The second heater 186 may include an electric resistance heating coil. The second heater 186 surrounds the closed container 126.

A third heater 188 for heating the first source gas to a second temperature is installed in the first pipe 140 between the closed container 126 and the fourth connecting member 158. The second temperature, for example, is in a range of about 180 to about 250° C., preferably 200° C. so as to prevent a reaction between the TiCl₄ gas and the NH₃ gas.

To prevent the TiCl₄ gas from being condensed, a fourth heater 190 for heating the second source gas to the second temperature is installed in the second pipe 142 between the second valve 166 and the first connecting member 152. Thus, when the first source gas and the second source gas are mixed with each other in the first connecting member 152, temperatures of the first and second source gases are not changed so that contaminants caused by temperature alterations of the first and second source gases may be reduced.

Particularly, when the first carrier gas is supplied to the main pipe 138 through the dipped pipe 128 and the fourth valve 170, the first heater 184 heats the first carrier gas to the first temperature. The first source gas formed by bubbling of the first carrier gas has a temperature substantially similar to the first temperature. The first source gas is supplied to the main pipe 138 through the first pipe 140 and the first valve 164. The third heater 188 heats the first source gas to the second temperature. Meanwhile, the NH₃ gas and the second carrier gas are supplied to the main pipe 138 through the second pipe 142 and the second valve 166. The fourth heater 190 heats the NH₃ gas and the second carrier gas to the second temperature.

The first and second source gases are supplied to the substrate 10 in the process chamber 102 through the main pipe 138 and the showerhead 106. A titanium nitride layer is formed on the substrate 10 having a processing temperature by reacting between the first source gas and the second source gas. Since the titanium nitride may be formed at a temperature of about 550 to 720° C., the processing temperature may be about 680° C.

As shown in FIGS. 1 and 2, a fifth heater 192 for heating the substrate to the processing temperature is disposed in the chuck 104. The fifth heater 192 may include an electric resistance heating coil. Alternatively, the fifth heater 192 may include a lamp assembly. The lamp assembly may include a plurality of halogen lamps, a lamp housing for receiving the halogen lamps to irradiate lights emitted from the halogen lamps to the chuck 104, and a transparent window for transmitting the lights that is disposed between the halogen lamps and the chuck 104.

The byproducts generated in forming the titanium nitride layer, a remaining gas, etc., may be removed from the processing chamber 102 by the vacuum system 110. The vacuum system 110 may include a vacuum pump 112, a vacuum pipe 114, and pressure-controlling valve 116.

After the titanium nitride is formed on the substrate 10, the purge gas is supplied to the processing chamber 102 from the third container 136 through the third pipe 144 and the third valve 168. In particular, the purge gas is supplied to the processing chamber 102 through the main pipe 138 and the showerhead 106. The purge gas is heated to the second temperature for preventing condensation of the TiCl₄ gas remaining in the main pipe 138, the showerhead 106, and the processing chamber 102. The purge gas is heated by the sixth heater 194 installed in the third pipe 144 between the third valve 168 and the sixth connecting member 162. Thus, a temperature change due to the supply of the purge gas may be prevented so that a contamination caused by the condensation of the remaining TiCl₄ gas in the main pipe 138, the showerhead 106, and the processing chamber 102 may be reduced.

Meanwhile, before the first source gas and the second source gas are supplied to the processing chamber 102, the first source gas is bypassed through the first bypassing pipe 148 and the seventh valve 176 to form a laminar flow. A seventh heater 196 for preventing condensation of the TiCl₄ gas is installed in the first bypassing pipe 148. The second source gas is bypassed through the second bypassing pipe 150 and the eighth valve 178.

FIG. 3 is a cross sectional view illustrating the sixth heater in FIG. 1.

Referring to FIG. 3, the sixth heater 194 may include a heating block 194b having a fluid flow passage 194a for transferring the purge gas to the main pipe 138, and an electric resistance heating coil 194c for heating the heating block 194b. The fluid flow passage 194a is connected to the third pipe 144. The fluid flow passage 194a has a spiral shape capable of heating the purge gas to the second temperature. The electric resistance heating coil 194 is built-in to the heating block 194b to surround the fluid flow passage 194a. For example, the electric resistance heating coil 194c has a coil shape having an inner diameter no less than that of the fluid flow passage 194a. In this embodiment, the heating block 194b may include a ceramic material.

Alternatively, the fluid flow passage 194a may have a zigzag pattern so as to sufficiently heat the purge gas. On the contrary, when a length of the third pipe 144 is sufficiently long in length, a heating jacket entirely surrounding the third pipe 144 may be used as the sixth heater 194.

Meanwhile, the third and fourth heaters 188 and 190 may have structures substantially identical to that of the sixth heater 194. Also, as shown in FIG. 1, a first heating jacket 198 surrounds the first pipe 140 between the closed container 126 of the first gas-supplying unit 122 and the third heater 188 so as to maintain the first temperature of the first source gas. A second heating jacket 199 surrounds the main pipe 138 so as to maintain the second temperatures of the first and second source gases, and the purge gas.

The first heater 184 may have a structure substantially identical to that of the sixth heater 194. When a length of the dipping pipe 128 is sufficiently long to provide the first temperature to the first carrier gas, a heating jacket may be used as the first heater 184. The seventh heater 196 may have a structure substantially identical to that of the sixth heater 194. A heating jacket may be used as the seventh heater 196.

According to the present embodiment, the first carrier gas is heated by the first heater 184 to the first temperature. Also, the first source gas is heated by the third heater 188 to the second temperature. Further, the second source gas and the purge gas is heated by the fourth heater 190 and the sixth heater 194 to the second temperature, respectively. The first source gas, the second source gas and the purge gas are maintained at the second temperature by the second heating jacket 199. That is, the temperatures of respective gases flowing through the gas supplying unit 120 are maintained between a temperature of condensation (e.g. 100° C.) and a reaction temperature (e.g. 280° C.) of the source gas so that the main pipe 138 and showerhead 106 are not contaminated with titanium or titanium nitride particles, or condensed TiCl₄ gas.

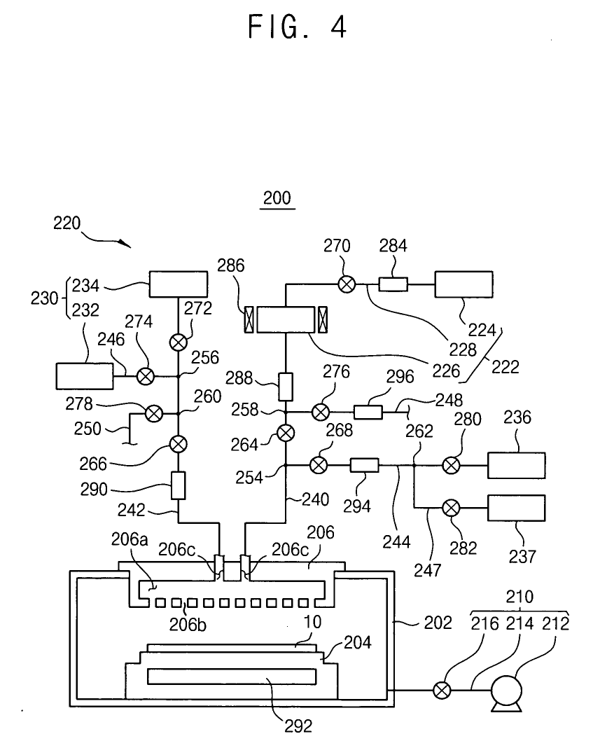

FIG. 4 is a schematic view illustrating an apparatus for forming a layer in accordance with another exemplary embodiment of the present invention.

An apparatus 200 for forming a layer in accordance with another embodiment of the present invention, as shown in FIG. 4, includes a processing chamber 202, a chuck 204, and a gas-supplying unit 220, etc.

A showerhead 206 is positioned at an upper portion of the processing chamber 202. The showerhead 206 uniformly supplies a first source gas, a second source gas, a purge gas, and a cleaning gas into the processing chamber 202. The processing chamber 202 is connected to a vacuum system 210 for exhausting reaction byproducts and remaining gases that are generated in forming a layer on a substrate 10 mounted on the chuck 204.

The gas-supplying unit 220 includes a first gas-supplying unit 222 for supplying the first source gas to the processing chamber 202, a second gas-supplying unit 230 for supplying the second source gas to the processing chamber 202, and the third gas-supplying unit 236 for supplying the purge gas to the showerhead 206. The gas-supplying unit 220 is connected to the showerhead 206 through a pipe unit.

The first gas-supplying unit 222 includes a first container 224 for containing a first carrier gas, a closed container 226 for receiving a liquid TiCl₄ solution, a dipped pipe 228 for bubbling the first carrier gas in the TiCl₄ solution. The second gas-supplying unit 230 includes a second container 232 for containing a second carrier gas, and an NH₃ tank 234 for supplying an NH₃ gas. The third gas-supplying unit 236 includes a third container for containing the purge gas.

The showerhead 206 includes a lower plate and an upper plate. The showerhead 206 has a space 206a for receiving the gases. The lower plate has a plurality of gas-spraying holes 206b for uniformly supplying the gases into the process chamber 202. The upper plate has a gas-supplying hole 206c for supplying the gases to the space 206a.

The showerhead 206 and the closed container 226 of the first gas-supplying unit 222 are connected through a first pipe 240. The showerhead 206 and the NH₃ tank 234 of the second gas-supplying unit 230 are connected through a second pipe 242. The third gas-supplying unit 236 is connected to the first pipe 240 through a third pipe 244. The second container 232 is connected to the second pipe 242 through a fourth pipe 246. As illustrated in FIG. 4, the purge gas is supplied to the showerhead 206 through the third pipe 244 and the first pipe 240. Alternatively, the third pipe 244 may be connected to the second pipe 242.

Meanwhile, a first connecting member 254 is connected between the first pipe 240 and the third pipe 244. A second connecting member 256 is connected between the second pipe 242 and the fourth pipe 246.

A first valve 264 for adjusting a flux of the first source gas is installed in the first pipe 240. A second valve 266 for adjusting a flux of the second source gas is installed in the second pipe 242. A third valve 268 for adjusting a flux of the purge gas is installed in the third pipe 244. A fourth valve 270 for adjusting a flux of the first carrier gas is installed in a dipped pipe 228. A fifth valve 272 for adjusting a flux of the NH₃ gas is installed in the second pipe 242 between the second connecting member 256 and the NH₃ tank 234 of the second gas-supplying unit 230. A sixth valve 274 for adjusting a flux of the second carrier gas is installed in the fourth pipe 246.

A first bypassing pipe 248 for bypassing the first source gas is connected to the first pipe 240 between the first valve 264 and the closed container 226 of the first gas-supplying unit 222 through a third connecting member 258. A second bypassing pipe 250 for bypassing the second source gas is connected to the second pipe 242 between the second valve 266 and the second connecting member 256 through a fourth connecting member 260. The seventh and eighth valves 276 and 278 are installed in the first and second bypassing pipes 248 and 250, respectively. Note, there is no respective first connecting member, like member 152 in the embodiment of FIG. 1, since first pipe 240 and second pipe 242 feed gases directly in to showerhead 206.

A fourth gas-supplying unit 237 for supplying the cleaning gas into the processing chamber 202 is connected to the third pipe 244 through the fifth pipe 247. In particular, the fifth pipe 247 is connected to the third pipe 244 between the third valve 268 and the third gas-supplying unit 236 through a fifth connecting member 262. A ninth valve 280 is installed in the third pipe 244 between the fifth connecting member 262 and the third gas-supplying unit 236. A tenth valve 282 is installed in the fifth pipe 247.

A first heater 284 for heating a first carrier gas that is transferred from the first container 224 is installed in the dipped pipe 228 between the fourth valve 270 and the first container 224. In this embodiment, the first heater 284 heats the first carrier gas to a first temperature of about 100° C. to about 180° C., preferably about 150° C.

To improve a vapor efficiency of the liquid TiCl₄ solution, the second heater 286 for heating the closed container 226 is connected to the closed container 226. The second heater 286 may include an electric resistance heating coil.

A third heater 288 for heating the first source gas to a second temperature is installed in a first pipe 240 between the closed container 226 and the third connecting member 258. In this embodiment, the second temperature may be about 180° C. to about 250° C., preferably about 200° C.

A fourth heater 290 for heating the second source gas to the second temperature is installed in the second pipe 242 between the second valve 266 and the showerhead 206. Thus, when the first source gas and the second source gas are mixed in the showerhead 206, temperatures of the first and second source gases are not changed so that a contamination due to a temperature alteration may be reduced.

The first and second source gases are supplied to the substrate disposed in the processing chamber 202 through the showerhead 206. Thus, a titanium nitride layer is formed on the substrate heated to a processing temperature by a reaction between the first and second source gases.

A fifth heater 292 for heating the substrate 10 to the processing temperature is built-in to the chuck 204. The fifth heater 292 may include an electric resistance heating coil or a plurality of lamps.

Meanwhile, the vacuum system 210 connected to the process chamber 202 may remove the byproducts and/or the remaining gases, which are generated in forming the titanium nitride layer, from the processing chamber 202. The vacuum system 210 may include a vacuum pump 212, a vacuum pipe 214 and a pressure-controlling valve 216.

After forming the titanium nitride layer on the substrate 10, the purge gas is supplied from the third container 236 to the processing chamber 202 through the third pipe 244 and the third valve 268. The purge gas is supplied to the processing chamber 202 through the third pipe 244, the first pipe 240, and the showerhead 206. The purge gas is heated to the second temperature in order to prevent condensation of the TiCl₄ gas remaining in the first pipe 240, the showerhead 206, and the processing chamber 202. The purge gas may be heated by the sixth heater 294 installed in the third pipe 244 between the third valve 268 and the fifth connecting member 262.

Meanwhile, before the first source gas and the second source gas are supplied to the processing chamber 202, the first source gas is bypassed through the first bypassing pipe 248 and the seventh valve 276 to form a laminar flow. A seventh heater 296 for preventing condensation of the TiCl₄ gas is installed in the first bypassing pipe 248. The second source gas is bypassed through the second bypassing pipe 250 and the eighth valve 278.

The above-mentioned elements are substantially identical to those in FIGS. 1 to 3. Thus, any further illustrations of the elements are omitted herein.

### Method of Forming a Layer

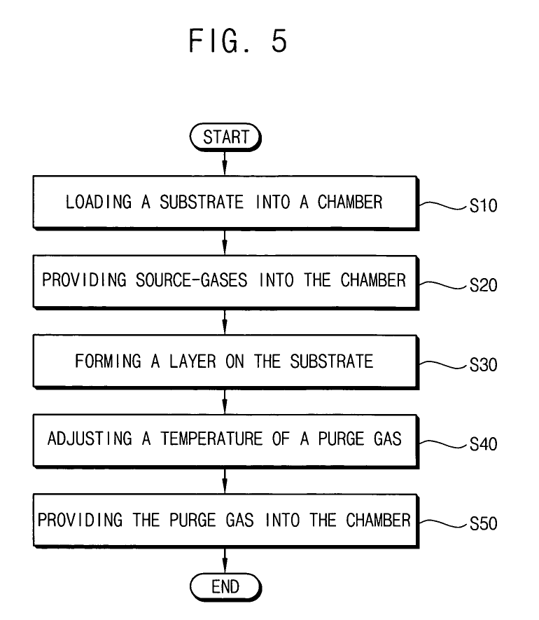

FIG. 5 is a flow chart illustrating a method of forming a layer in accordance with one exemplary embodiment of the present invention.

Referring to FIG. 5, in step S10, a substrate 10 such as a silicon wafer is loaded into a processing chamber so as to form a layer such as a titanium nitride layer.

Preferably, the substrate 10 is disposed on a chuck positioned in the processing chamber. After loading the substrate 10 into the processing chamber, a processing temperature and a processing pressure are adjusted so as to form a layer.

In step S20, in order to form the layer on the substrate 10, source gases are provided from a gas-supplying unit into the processing chamber through a pipe connected to the gas-supplying unit and a showerhead.

In an exemplary embodiment, the source gases may include a first source gas and second source gas. The first source gas may include a TiCl₄ gas and a first carrier gas for carrying the TiCl₄ gas from the gas-supplying unit into the processing chamber. The second source gas may include a NH₃ gas and a second carrier gas for carrying the NH₃ gas the gas-supplying unit into the processing chamber. In an exemplary embodiment, the first and second source gases are provided into the showerhead disposed in the processing chamber through the pipe.

Also in an exemplary embodiment, the first and second source gases are heated to a second temperature for suppressing a reaction of the first source gas with the second source gas in the pipe. The first and second source gases, for example, may be heated to a temperature of about 180° C. to about 250° C. For example, the TiCl₄ gas of the first source gas may be formed by bubbling the first carrier gas in a TiCl₄ solution.

A temperature of the first carrier gas for generating the bubbling may be heated to be higher than a condensing temperature of the TiCl₄ gas. The first carrier gas may have a first temperature of about 100° C. to about 180° C.

In step S30, first and second source gases are provided into the processing chamber to form a layer such as a titanium nitride layer on the substrate.

After forming the titanium nitride layer by using the first and second source gases, byproducts and remaining gases that are generated in forming the titanium nitride layer are removed from the process chamber through a vacuum system.

In step S40, after removing the byproduct or the remaining gas from the processing chamber by the vacuum system, a temperature of the purge gas provided from the gas-supplying unit is adjusted. In an exemplary embodiment, the purge gas may include an argon gas or a nitrogen gas. These can be used alone or in a combination thereof.

When a temperature of the TiCl₄ gas remaining in the pipe, the showerhead and the processing chamber and a temperature of the purge gas supplied from the gas-supplying unit to the processing chamber are different from each other, the TiCl₄ gas may be condensed in the pipe, the showerhead and the processing chamber. Thus, the purge gas provided from the gas-supplying unit is heated for preventing the condensing of the TiCl₄ gas.

In exemplary embodiment, a temperature of the purge gas is substantially identical to that of the first and second source gases. Preferably, the purge gas has a temperature of about 180° C. to about 250° C.

For example, the purge gas, which is provided to the gas-supplying unit, in the pipe connected between the gas-supplying unit and the showerhead may be heated. Preferably, the purge gas may be heated by an electric resistance heating coil, a heating jacket, etc.

In step S50, the purge gas having a temperature substantially identical to that of the first and second source gases is provided into the processing chamber through the pipe and showerhead.

According to the present invention, the first and second source gases, and the purge gas have substantially identical temperatures. Thus, the temperature alteration due to mixing of the gases may be suppressed. As a result, the condensation of the TiCl₄ gas due to the temperature alteration may be reduced so that the apparatus and the semiconductor device may not be contaminated.

Also, since the first and second source gases are heated to a temperature of about 180° C. to about 250° C. lower than a reaction temperature between the TiCl₄ gas and the NH₃ gas, titanium or titanium nitride may not be generated in the pipes and the showerhead.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. An apparatus for forming a layer, comprising:
a processing chamber;
a chuck, arranged within the processing chamber, for supporting a substrate;
a gas-supplying unit for supplying to the processing chamber a source gas that is used for forming a layer on the substrate and a purge gas that is used for purging the inside of the processing chamber;
a pipe unit for transferring the source and purge gases to the processing chamber; and
a heater for heating within the pipe unit the purge gas that is supplied to the processing chamber to a purge gas temperature that is between a temperature of condensation and a reaction temperature of the source gas.

2. The apparatus of claim 1, wherein the source gas comprises a first source gas including a TiCl₄ gas and a first carrier gas, and a second source gas includes an NH₃ gas and a second carrier gas.

3. The apparatus of claim 2, wherein the gas-supplying unit comprises a first gas-supplying unit for supplying the first source gas to the processing chamber, a second gas-supplying unit for supplying the second source gas to the processing chamber, and a third gas-supplying unit for supplying the purge gas to the processing chamber.

4. The apparatus of claim 3, wherein the pipe unit comprises:
a main pipe for transferring the source gases and the purge gas to the processing chamber;
a first pipe connected to the main pipe to transfer the first source gas to the processing chamber;
a second pipe connected to the main pipe to transfer the second source gas to the processing chamber; and
a third pipe connected to the first pipe to transfer the purge gas to the processing chamber through the first pipe,
wherein the heater is connected to the third pipe.

5. The apparatus of claim 4, further comprising:
a second heater connected to the first pipe to heat the first source gas; and
a third heater connected to the second pipe to heat the second source gas.

6. The apparatus of claim 3, wherein the pipe unit comprises:
a first pipe to transfer the first source gas to the processing chamber;
a second pipe to transfer the second source gas to the processing chamber; and
a third pipe connected to the first pipe to transfer the purge gas to the processing chamber through the first pipe,
wherein the heater is connected to the third pipe.

7. The apparatus of claim 3, wherein the first gas-supplying unit comprises:
a vessel for receiving a TiCl₄ solution;
a container for containing the first carrier gas; and
a dipped pipe for generating the first source gas by bubbling the first carrier gas through the TiCl₄ solution received within the vessel, the dipping pipe including a first end that is connected to the container and a second end that is dipped into the TiCl₄ solution.

8. The apparatus of claim 7, wherein the first gas-supplying unit further comprises a second heater connected to the dipped pipe to heat the first carrier gas to a first carrier gas temperature above a condensation temperature of the first source gas.

9. The apparatus of claim 1, further comprising a showerhead for uniformly supplying the source gas and the purge gas to the processing chamber, the showerhead being positioned in the processing chamber and being connected to the pipe unit.

10. The apparatus of claim 1, wherein the heater has a spiral fluid passage for transferring the purge gas.

11. The apparatus of claim 1, wherein the heater is located outside of the processing chamber.
a heating block having the spiral fluid passage; and
an electric resistance heating coil for heating the heating block.

12. The apparatus of claim 1, wherein the heater is located outside of the processing chamber.

13. A method of forming a layer on a semiconductor substrate, comprising:
positioning a substrate within a processing chamber;
supplying a source gas into the chamber to form a layer on the substrate, said source gas being supplied into the chamber at a source gas temperature between a condensation temperature of the source gas and a reaction temperature; and
after supplying the source gas into the chamber, providing a purge gas into the processing chamber at a purge gas temperature between a condensation temperature of the source gas and a reaction temperature of the source gas to purge an inner space of the processing chamber.

14. The method of claim 13, wherein the source gas comprises a first source gas including a TiCl₄ gas and a first carrier gas, and a second source gas includes an NH₃ gas and a second carrier gas.

15. The method of claim 14, wherein the purge gas temperature is between about 180° C. to about 250° C.

16. The method of claim 14, wherein the first and second source gases are supplied through separate sub-pipes connected, further comprising heating the first and second source gases to a source gas temperature to prevent a reaction between the first source gas and the second source gas in the pipe.

17. The method of claim 16, wherein the purge gas temperature is substantially identical to the source gas temperature.

18. The method of claim 14, further comprising bubbling the first carrier gas in a TiCl₄ solution for forming the TiCl₄ gas.

19. The method of claim 18, before bubbling the first carrier gas, further comprising heating the first carrier gas to a carrier gas temperature that is higher than a condensing temperature of the TiCl₄ gas.

20. The method of claim 19, wherein the carrier gas temperature is between about 100° C. to 180° C.

21. The method of claim 13, wherein the purge gas comprises an argon gas or a nitrogen gas.

22. The method of claim 14, wherein the source gas and purge gas are both supplied through a pipe into the chamber.

23. The method of claim 13, further including heating the substrate to a processing temperature above the reaction temperature of the source gas.
